(19) United States
(12) Patent Application Publication
(10) Pub. No.: US 2024/0294854 A1
(43) Pub. Date: Sep. 5, 2024

(54) CLEANING LIQUID FOR REMOVING CERIUM COMPOUND, CLEANING METHOD, AND METHOD FOR PRODUCING SEMICONDUCTOR WAFER

(71) Applicant: MITSUBISHI CHEMICAL CORPORATION, Tokyo (JP)

(72) Inventors: Kenichi KIYONO, Tokyo (JP); Tomohiro KUSANO, Tokyo (JP); Kan TAKESHITA, Tokyo (JP); Mari ABE, Tokyo (JP); Kanako MINAYOSHI, Tokyo (JP)

(73) Assignee: MITSUBISHI CHEMICAL CORPORATION, Tokyo (JP)

(21) Appl. No.: 18/659,733

(22) Filed: May 9, 2024

Related U.S. Application Data
(63) Continuation of application No. PCT/JP2022/031767, filed on Aug. 23, 2022.

(30) Foreign Application Priority Data
Nov. 10, 2021 (JP) 2021-183700

(51) Int. Cl. C11D 7/26; C11D 7/08; H01L 21/02; H01L 21/3105

(52) U.S. Cl. CPC C11D 7/261; C11D 7/08; H01L 21/02065; H01L 21/31053

(57) ABSTRACT

A cleaning liquid for removing a cerium compound contains (A) a six-membered ring compound having two or more hydroxy groups, and (B) an inorganic acid compound, and a mass ratio of the component (B) to the component (A) is 0.05 to 0.6. The component (A) may contain at least one selected from the group consisting of catechol, resorcinol, hydroquinone, pyrogallol, and methylcatechol.

### CROSS-REFERENCE TO RELATED APPLICATIONS

This application is a continuation of International Application No. PCT/JP2022/031767, filed on Aug. 23, 2022, and claims the benefit of priority to Japanese Application No. 2021-183700, filed on Nov. 10, 2021. The content of each of these applications is hereby incorporated by reference in its entirety.

### TECHNICAL FIELD

The present invention relates to a cleaning liquid for removing a cerium compound, a cleaning method, and a method for producing a semiconductor wafer.

### BACKGROUND ART

A semiconductor wafer is produced by deposition of a metal film working as a wiring and an interlayer dielectric on a silicon substrate, subsequently conducting a surface planarization treatment by means of a chemical mechanical polishing (hereinafter referred to as “CMP”) step using an abrasive composed of an aqueous slurry containing fine abrasive particles, and then stacking new layers on the planarized surface. In microfabrication of the semiconductor wafer, each layer is required to have planarity with high precision, and importance of the planarization treatment by means of CMP is very high.

In semiconductor device production steps, a device isolation structure based on a shallow trench isolation (STI) suitable for miniaturization is used instead of local oxidation of silicon (LOCOS) in the related art in order to electrically isolate devices such as a transistor. An inter layer dielectric (ILD) is used between wiring layers. The STI and the ILD are made by forming a silicon oxide film using tetraethyl orthosilicate (TEOS) or the like as a raw material and performing planarization in a CMP step.

On the surface of the semiconductor wafer after the CMP step, many fine abrasive particles of a polishing agent used in the CMP step, and organic residues derived from organic compounds contained in the slurry are present. Therefore, in order to remove the fine abrasive particles and the organic residues, the semiconductor wafer after the CMP step is subjected to a cleaning step.

In recent years, cerium-based fine abrasive particles such as cerium oxide have been used in the CMP step of a silicon oxide film or a silicon nitride film in order to increase a polishing rate. The cerium-based fine abrasive particles form bonds with surfaces of the silicon oxide film and the silicon nitride film during the CMP step, and therefore, the cerium-based fine abrasive particles are difficult to remove during the cleaning step.

Therefore, although cleaning has been commonly performed using a strong chemical such as diluted hydrofluoric acid and a sulfuric acid/hydrogen peroxide mixture, various cleaning liquids have been proposed in place of diluted hydrofluoric acid or the sulfuric acid/hydrogen peroxide mixture due to problems such as safety and waste liquid treatment. For example, Patent Literature 1 discloses a cleaning liquid containing a strong acid.

### CITATION LIST

### Patent Literature

Patent Literature 1: JP2012-134357A

### SUMMARY OF INVENTION

### Technical Problem

However, the cleaning liquid disclosed in Patent Literature 1 contains ascorbic acid, and thus there is a problem that the cleaning liquid has poor removability of the cerium compound. In particular, ascorbic acid in an aqueous solution undergoes a self-decomposition reaction by oxygen, and thus has a problem of poor handleability.

The present invention has been made in view of such problems, and an object of the present invention is to provide a cleaning liquid excellent in removability of a cerium compound.

### Solution to Problem

Previously, the cleaning liquids containing various components have been studied. As a result of intensive studies, the present inventors have found a cleaning liquid containing a component (A) and a component (B), which will be described below, at a predetermined mass ratio, and have found that the cleaning liquid has excellent removability of a cerium compound.

That is, the gist of the present invention is as follows.

<1> A cleaning liquid for removing a cerium compound, the cleaning liquid comprising the following component (A) and component (B), wherein a mass ratio of the component (B) to the component (A) is 0.05 to 0.6:
component (A): a six-membered ring compound having two or more hydroxy groups; and
component (B): an inorganic acid compound.

<2> The cleaning liquid according to <1>, wherein the component (A) contains at least one selected from the group consisting of catechol, resorcinol, hydroquinone, pyrogallol, and methylcatechol.

<3> The cleaning liquid according to <1> or <2>, wherein the component (A) contains pyrogallol.

<4> The cleaning liquid according to any one of <1> to <3>, wherein the component (B) contains at least one selected from the group consisting of sulfuric acid, nitric acid, hydrochloric acid, phosphoric acid, and phosphorous acid.

<5> The cleaning liquid according to any one of <1> to <4>, wherein the component (B) contains sulfuric acid.

<6> The cleaning liquid according to any one of <1> to <5>, further comprising the following component (C),
component (C): a water-soluble organic polymer.

<7> The cleaning liquid according to <6>, wherein the component (C) contains at least one selected from a polycarboxylic acid and a salt thereof.

<8> The cleaning liquid according to any one of <1> to <7>, wherein the cleaning liquid has a pH of 1 to 4.

<9> The cleaning liquid according to any one of <1> to <8>, which is used for cleaning after chemical mechanical polishing.

<10> The cleaning liquid according to any one of <1> to <9>, which is used for removing the cerium compound on a silicon oxide film and/or a silicon nitride film.

<11> A cleaning method comprising removing a cerium compound using the cleaning liquid according to any one of <1> to <10>.

<12> A method for producing a semiconductor wafer, the method comprising: removing a cerium compound using the cleaning liquid according to any one of <1> to <10>.

<13> The method for producing a semiconductor wafer according to <12>, further comprising: performing chemical mechanical polishing using an abrasive containing a cerium compound.

### Advantageous Effects of Invention

A cleaning liquid according to the present invention is excellent in removability of a cerium compound.

In addition, a cleaning method according to the present invention is excellent in removability of the cerium compound.

Further, a method for producing a semiconductor wafer according to the present invention includes a cleaning step excellent in removability of a cerium compound, so that it is possible to prevent malfunction of a semiconductor device.

### DESCRIPTION OF EMBODIMENTS

Hereinafter, embodiments of the present invention are specifically described, but it should not be construed that the present invention is limited to the following embodiments, and the present invention can be carried out by making various changes within the scope of a gist thereof. In the present description, the expression “to” is used as an expression including numerical values or physical property values before and after the expression.

### Cleaning Liquid

A cleaning liquid according to the present invention is used for removing a cerium compound, and is suitably used for removing a cerium compound on a silicon oxide film and/or a silicon nitride film, and particularly suitably used for removing a cerium compound on the silicon oxide film.

The “cerium compound on the silicon oxide film and/or the silicon nitride film” means at least one cerium compound selected from the group consisting of a cerium compound on the silicon oxide film and a cerium compound on the silicon nitride film.

Hereinafter, each component will be described in detail.

### Component (A)

The cleaning liquid according to the present invention contains the following component (A).
component (A): a six-membered ring compound having two or more hydroxy groups.

When the cleaning liquid according to the present invention contains the component (A), the component (A) selectively acts on cerium ions and can break the bonds between the cerium compound and a silicon oxide without damaging the silicon oxide film or the silicon nitride film, and the cleaning liquid according to the present invention is excellent in the removability of the cerium compound and the low damaging property to the silicon oxide film or the silicon nitride film.

The component (A) is preferably a six-membered ring compound having 2 to 5 hydroxy groups, more preferably a six-membered ring compound having 2 to 4 hydroxy groups, and still more preferably a six-membered ring compound having 2 to 3 hydroxy groups from the viewpoint of obtaining excellent reducing power.

The component (A) may be a six-membered ring compound having a substituent in addition to two or more hydroxy groups. Examples of the substituent include an alkyl group, a vinyl group, and a carboxy group, and among these, an alkyl group having 1 to 3 carbon atoms is preferred.

The component (A) is preferably an aromatic six-membered ring compound having two or more hydroxy groups from the viewpoint of obtaining excellent reducing power.

Specific examples of the component (A) include catechol, resorcinol, hydroquinone, pyrogallol, methylcatechol, and phloroglucinol. One of these components (A) may be used alone, or two or more thereof may be used in combination.

Among these components (A), catechol, resorcinol, hydroquinone, pyrogallol, and methylcatechol are preferred, pyrogallol and catechol are more preferred, and pyrogallol is still more preferred from the viewpoint of obtaining excellent reducing power in an acidic environment.

### Component (B)

The cleaning liquid according to the present invention contains the following component (B).
component (B): an inorganic acid compound.

Since the cleaning liquid according to the present invention contains the component (B), an ionization reaction rate of cerium and the stability of the cleaning liquid are improved.

Specifically, the ionization reaction rate of cerium is improved and a self-decomposition reaction of the component (A) is prevented, and therefore, the removability of the cerium compound is improved.

Examples of the component (B) include sulfuric acid, nitric acid, hydrochloric acid, phosphoric acid, phosphorous acid, and perchloric acid. One of these components (B) may be used alone, or two or more thereof may be used in combination.

Among these components (B), sulfuric acid, nitric acid, hydrochloric acid, phosphoric acid, phosphorous acid, and perchloric acid are preferred, sulfuric acid, nitric acid, hydrochloric acid, phosphoric acid, and phosphorous acid are more preferred, sulfuric acid, nitric acid, and phosphoric acid are still more preferred, and sulfuric acid is particularly preferred from the viewpoint of excellent proton donating ability.

### Component (C)

From the viewpoint of dispersing the cerium compound and improving the removability of the cerium compound, the cleaning liquid according to the present invention preferably further contains the following component (C).
component (C): a water-soluble organic polymer.

Examples of the component (C) include a polycarboxylic acid and a salt of a polycarboxylic acid. Examples of the polycarboxylic acid include polyacrylic acid and polymethacrylic acid. Examples of the salt of the polycarboxylic acid include a salt of a polyacrylic acid and a salt of a polymethacrylic acid. One of these components (C) may be used alone, or two or more thereof may be used in combination.

Among these components (C), a polycarboxylic acid and a salt of a polycarboxylic acid are preferred, a polycarboxylic acid is more preferred, and a polyacrylic acid is still more preferred from the viewpoint of obtaining easy dissolution in an acidic aqueous solution.

The polycarboxylic acid may be a homopolymer of a carboxylic acid-containing monomer or a copolymer of a carboxylic acid-containing monomer and another monomer.

A weight average molecular weight of the component (C) is preferably 100 to 20,000, and more preferably 200 to 10,000. When the weight average molecular weight of component (C) is 100 or more, the cerium compound is dispersed, and the removability of the cerium compound is improved. When the weight average molecular weight of the component (C) is 20,000 or less, the component (C) is easily dissolved in water.

### Component (D)

From the viewpoint of adjusting the pH of the cleaning liquid, the cleaning liquid according to the present invention preferably further contains the following component (D).
component (D): a pH adjusting agent

Examples of the component (D) include an alkali. Among these components (D), alkali is preferred because the cerium compound can be dispersed, ammonia and a quaternary ammonium salt are more preferred because no metal component is contained, and ammonia is still more preferred.

### Component (E)

From the viewpoint of improving the fine particle removability, the cleaning liquid according to the present invention preferably further contains the following component (E).
component (E): water

Examples of the water include ion-exchanged water, distilled water, and ultrapure water. Among these, ultrapure water is preferred from the viewpoint of further improving the removability of cerium compounds.

### Other Components

The cleaning liquid according to the present invention may contain components other than the components (A) to (E) to the extent that the effects of the present invention are not impaired.

Examples of the other components include a chelating reagent, a surfactant, and an etching inhibitor.

### Physical Properties of Cleaning Liquid

The pH of the cleaning liquid is preferably 1 to 4, more preferably 1.5 to 3, and still more preferably 1.5 to 2.5. When the pH of the cleaning liquid is 1 or higher, damage to a member such as a brush used in a step of cleaning a semiconductor wafer or the like can be prevented. When the pH of the cleaning liquid is 4 or lower, the self-decomposition reaction of the component (A) is prevented, and the removability of the cerium compound is improved.

### Mass Ratio of Components

The mass ratio of the component (B) to the component (A) (mass of component (B)/mass of component (A)) is 0.05 to 0.6, preferably 0.07 to 0.55, more preferably 0.1 to 0.5, and still more preferably 0.2 to 0.4. When the mass ratio of the component (B) to the component (A) is 0.05 or more, the removability of the cerium compound is improved due to the effect of promoting the ionization reaction and the prevention of the self-decomposition of the component (A). When the mass ratio of the component (B) to the component (A) is 0.6 or less, the removability of the cerium compound and the low damaging property to the silicon oxide film and the silicon nitride film are improved due to the reducing power.

When the cleaning liquid according to the present invention contains the component (C), a mass ratio of the component (C) to the component (A) (mass of the component (C)/mass of the component (A)) is preferably 0.001 to 10, more preferably 0.005 to 2, and still more preferably 0.01 to 1. When the mass ratio of the component (C) to the component (A) is 0.001 or more, the removability of the cerium compound is further improved due to the dispersion effect. In addition, when the mass ratio of the component (C) to the component (A) is 10 or less, the removability of the cerium compound and the low damaging property to the silicon oxide film and the silicon nitride film are improved due to the reducing power.

When the cleaning liquid according to the present invention contains the component (C), a mass ratio of the component (C) to the component (B) (mass of the component (C)/mass of the component (B)) is preferably 0.001 to 10, more preferably 0.005 to 2, and still more preferably 0.01 to 1. When the mass ratio of the component (C) to the component (B) is 0.001 or more, the removability of the cerium compound is further improved due to the dispersion effect. When the mass ratio of the component (C) to the component (B) is 10 or less, the removability of the cerium compound is improved due to the effect of promoting the ionization reaction and the effect of preventing the self-decomposition of the component (A).

### Content of Each Component in Cleaning Liquid

The content of the component (A) is preferably 0.001 mass % to 30 mass %, more preferably 0.005 mass % to 20 mass %, and still more preferably 0.01 mass % to 1 mass % in 100 mass % of the cleaning liquid. When the content of the component (A) is 0.001 mass % or more, the removability of the cerium compound and the low damaging property to the silicon oxide film and the silicon nitride film are improved due to the reducing power. When the content of the component (A) is 30 mass % or less, the component (A) can be sufficiently dissolved in the component (E) when the cleaning liquid contains the component (E), and the production cost of the cleaning liquid can be reduced.

The content of the component (B) is preferably 0.0001 mass % to 30 mass %, more preferably 0.0005 mass % to 20 mass %, still more preferably 0.001 mass % to 1 mass % in 100 mass % of the cleaning liquid. When the content of the component (B) is 0.0001 mass % or more, the removability of the cerium compound is improved due to the effect of promoting the ionization reaction and the effect of preventing the self-decomposition of the component (A). When the content of the component (B) is 30 mass % or less, the component (B) can be sufficiently dissolved in the component (E) when the cleaning liquid contains the component (E), and the production cost of the cleaning liquid can be reduced.

In a case where the cleaning liquid according to the present invention contains the component (C), the content of the component (C) is preferably 0.001 mass % to 10 mass %, more preferably 0.005 mass % to 5 mass %, and still more preferably 0.01 mass % to 0.2 mass % in 100 mass % of the cleaning liquid. When the content of the component (C) is 0.001 mass % or more, the removability of the cerium compound is improved due to the dispersion effect. When the content of the component (C) is 10 mass % or less, the component (C) can be sufficiently dissolved in the component (E) when the cleaning liquid contains the component (E), and the production cost of the cleaning liquid can be reduced.

In a case where the cleaning liquid according to the present invention contains the component (D), the content of the component (D) is preferably 0.0001 mass % to 30 mass %, more preferably 0.0005 mass % to 20 mass %, and still more preferably 0.001 mass % to 1 mass % in 100 mass % of the cleaning liquid. When the content of the component (D) is 0.0001 mass % or more, the pH of the cleaning liquid can be easily adjusted. When the content of the component (D) is 30 mass % or less, the pH of the cleaning liquid can be adjusted without impairing the effects of the present invention.

In a case where the cleaning liquid according to the present invention contains other components, the content of the other components is preferably 20 mass % or less, more preferably 0.0001 mass % to 10 mass %, still more preferably 0.001 mass % to 1 mass % in 100 mass % of the cleaning liquid. When the content of the other components is 20 mass % or less, the effect of the other components can be imparted without impairing the effects of the present invention.

When the cleaning liquid according to the present invention contains the component (E), the content of the component (E) is preferably the balance of the components (the components (A) to (D) and other components) other than the component (E).

### Method for Producing Cleaning Liquid

A method for producing the cleaning liquid according to the present invention is not particularly limited, and the cleaning liquid can be produced by mixing the component (A) and the component (B), and, if necessary, the component (C) to the component (E) and other components.

The order of mixing is not particularly limited, and all the components may be mixed at one time, or some components may be mixed in advance and then the remaining components may be mixed.

In the method for producing the cleaning liquid according to the present invention, each component may be blended to have a content suitable for cleaning, or a cleaning liquid containing each component other than the component (E) may be prepared at a high content, and then the cleaning liquid may be prepared by diluting with the component (E) before cleaning because transportation and storage costs can be reduced.

The dilution ratio can be appropriately set according to an object to be cleaned, and is preferably 30 times to 150 times, and more preferably 40 times to 120 times.

### Object to be Cleaned

Examples of the object to be cleaned of the cleaning liquid according to the present invention include a semiconductor wafer, glass, metals, ceramics, resins, magnetic materials, and superconductors. Among these objects to be cleaned, an object having a surface from which a silicon oxide film or a silicon nitride film is exposed is preferred, a semiconductor wafer having a surface from which a silicon oxide film or a silicon nitride film is exposed is more preferred, and a semiconductor wafer having a surface from which a silicon oxide film is exposed is still more preferred from the viewpoint of remarkably enhancing the effect of the present invention.

On the surface of the semiconductor wafer having the surface from which the silicon oxide film and the silicon nitride film are exposed, a metal may coexist in addition to the silicon oxide and the silicon nitride.

### Types of Cleaning Step

Because it is excellent in removability of the cerium compound, the cleaning liquid according to the present invention can be suitably used for the cleaning after the chemical mechanical polishing.

The chemical mechanical polishing (CMP) step refers to a step of mechanically processing and planarizing the surface of a semiconductor wafer. In general, in the CMP step, using a dedicated device, a back side of the semiconductor wafer is attached to a jig called a platen, and the surface of the semiconductor wafer is pressed against a polishing pad, and an abrasive containing abrasive particles is dropped onto the polishing pad to polish the surface of the semiconductor wafer.

### CMP

CMP is performed by rubbing an object to be polished against the polishing pad using an abrasive.

The abrasive is not particularly limited as long as it is insoluble in water and can polish an object to be polished. From the viewpoint of sufficiently exhibiting the effect of the cleaning liquid according to the present invention, fine abrasive particles are preferred, and fine abrasive particles of a cerium compound are more preferred.

The fine abrasive particles may contain colloidal silica (SiO₂), fumed silica (SiO₂), or alumina (Al₂O₃) in addition to the fine abrasive particles of the cerium compound.

Examples of the cerium compound include cerium oxide and cerium hydroxide. One of these cerium compounds may be used alone, or two or more thereof may be used in combination. Among these cerium compounds, cerium oxide and cerium hydroxide are preferred, and cerium oxide is more preferred from the viewpoint of obtaining excellent in polishing rates and low scratch properties.

In addition to the fine abrasive particles, additives such as an oxidizing agent and a dispersing agent may be contained in the abrasive. In particular, in CMP for a semiconductor wafer having a surface on which a metal is exposed, an anticorrosive is often contained because the metal is easily corroded.

When the cleaning liquid according to the present invention is applied to a semiconductor wafer having a surface on which a silicon oxide film or a silicon nitride film is exposed after polishing with an abrasive containing such fine abrasive particles of a cerium compound, contamination of the semiconductor wafer derived from the cerium compound can be extremely effectively removed.

### Cleaning Conditions

A method for cleaning the object to be cleaned is preferably a method of bringing the cleaning liquid according to the present invention into direct contact with the object to be cleaned.

Examples of the method of bringing the cleaning liquid according to the present invention into direct contact with the object to be cleaned include: a dipping method in which a cleaning tank is filled with the cleaning liquid according to the present invention to immerse the object to be cleaned; a spin method for rotating the object to be cleaned at a high speed while flowing from a nozzle the cleaning liquid according to the present invention onto the object to be cleaned; and a spray method for spraying the cleaning liquid according to the present invention onto the object to be cleaned for cleaning. Among these methods, the spin method and the spray method are preferred because more efficient contamination elimination can be performed in a short time.

Examples of an apparatus for performing such cleaning include a batch cleaning apparatus for simultaneously cleaning multiple objects to be cleaned, which are accommodated in a cassette, and a single wafer cleaning apparatus for mounting a single object to be cleaned on a holder and performing cleaning. Among these apparatuses, a single wafer cleaning apparatus is preferred because the cleaning time can be shortened and the use of the cleaning liquid according to the present invention can be reduced.

As the cleaning method for an object to be cleaned, a cleaning method by means of physical force is preferred because the removability of contamination caused by fine particles attached to the object to be cleaned is further improved and the cleaning time can be shortened, scrub cleaning using a cleaning brush and ultrasonic cleaning with a frequency of 0.5 megahertz or more are more preferred, and scrub cleaning using a resin brush is still more preferred because of being more suitable for cleaning after CMP.

The material of the resin brush is not particularly limited, and polyvinyl alcohol and polyvinyl formal are preferred because the resin brush itself can be easily produced.

The cleaning temperature may be room temperature, and the cleaning liquid may be heated to 30° C. to 70° C. as long as the performance of the semiconductor wafer is not impaired.

### Cleaning Method

As described above, the cleaning method according to the present invention is a method including the step of removing the cerium compound on the silicon oxide film and/or the silicon nitride film using the cleaning liquid according to the present invention.

### Method for Producing Semiconductor Wafer

The method for producing a semiconductor wafer according to the present invention is a method including a step of removing the cerium compound on the silicon oxide film and/or the silicon nitride film using the cleaning liquid according to the present invention, and preferably includes a step of performing chemical mechanical polishing using an abrasive containing the cerium compound.

### EXAMPLES

Hereinafter, the present invention is demonstrated further more concretely by ways of Examples, but the present invention is not limited to following Examples, unless the gist of the present invention is exceeded.

### Raw Material

### Component (A):

pyrogallol (manufactured by FUJIFILM Wako Pure Chemical Corporation)
catechol (manufactured by FUJIFILM Wako Pure Chemical Corporation)
ascorbic acid (manufactured by FUJIFILM Wako Pure Chemical Corporation)

### Component (B):

sulfuric acid (manufactured by FUJIFILM Wako Pure Chemical Corporation)
nitric acid (manufactured by FUJIFILM Wako Pure Chemical Corporation)

### Component (E): Water

### Measurement of pH

The pH of each of the cleaning liquids obtained in Examples and Comparative Examples was measured with a pH meter (model name “D-74”, manufactured by Horiba, Ltd.) while the cleaning liquid was stirred with a magnetic stirrer.

### Measurement of Remaining Amount of Cerium Oxide

A silicon substrate on which a silicon oxide film was formed by a plasma chemical vapor deposition (CVD) method using tetraethoxysilane (TEOS) was cut into a size of 25 mm×40 mm. Next, the silicon substrate was subjected to the chemical mechanical polishing (CMP) for 30 seconds using an abrasive containing cerium oxide (aqueous dispersion of fine particles of cerium oxide having a particle diameter of 200 nm or less) and a polishing pad (trade name “IC 1000”, manufactured by NITTA DuPont Incorporated.). Next, a polyvinyl alcohol brush was pressed against the silicon substrate at 150 rpm for 30 seconds while flowing each of the cleaning liquids obtained in Examples and Comparative Examples at a flow rate of 100 ml/min to clean the silicon substrate. Further, the silicon substrate was subsequently cleaned under the same conditions while flowing the water under the same conditions. The silicon substrate was dried, and an amount of cerium oxide (atoms/cm²) remaining on a surface of the silicon substrate was measured using a total reflection X-ray fluorescence spectrometer (model name “NANOHUNTER II”, manufactured by Rigaku Corporation).

### Example 1

The components were mixed such that the content of pyrogallol was 0.38 mass % (component (A)), the content of sulfuric acid was 0.049 mass % (component (B)), and the balance was water (component (E)) in 100 mass % of the cleaning liquid, thereby obtaining the cleaning liquid.

The evaluation results of the obtained cleaning liquids are shown in Table 1.

### Examples 2 to 8, Comparative Examples 1 to 9

Cleaning liquids were obtained by performing same operations as in Example 1 except that the types and contents of the components (A) and (B) were changed to those of the raw materials shown in Table 1.

The evaluation results of the obtained cleaning liquids are shown in Table 1.

TABLE 1

| | | | | | | | Remaining amount |
|---|---|---|---|---|---|---|---|
| | Component (A) | | Component (B) | | Mass ratio | | of cerium oxide |
| | Type | mass % | Type | mass % | (B)/(A) | pH | (atoms/cm²) |
| Example 1 | Pyrogallol | 0.38 | Sulfuric acid | 0.049 | 0.13 | 2.1 | 1.59 × 10¹¹ |
| Example 2 | Pyrogallol | 0.38 | Sulfuric acid | 0.098 | 0.26 | 1.8 | 9.00 × 10¹⁰ |
| Example 3 | Pyrogallol | 0.38 | Sulfuric acid | 0.147 | 0.39 | 1.7 | 9.93 × 10¹⁰ |
| Example 4 | Pyrogallol | 0.51 | Sulfuric acid | 0.098 | 0.19 | 1.8 | 2.45 × 10¹¹ |
| Example 5 | Pyrogallol | 0.38 | Nitric acid | 0.031 | 0.08 | 2.3 | 3.53 × 10¹¹ |
| Example 6 | Pyrogallol | 0.38 | Nitric acid | 0.063 | 0.17 | 2.0 | 3.92 × 10¹¹ |
| Example 7 | Pyrogallol | 0.38 | Nitric acid | 0.094 | 0.25 | 1.9 | 2.98 × 10¹¹ |
| Example 8 | Catechol | 0.38 | Sulfuric acid | 0.098 | 0.26 | 1.9 | 4.99 × 10¹¹ |
| Comparative | Pyrogallol | 0.38 | — | — | — | 2.7 | 5.40 × 10¹¹ |
| Example 1 | | | | | | | |
| Comparative | Catechol | 0.38 | — | — | — | 5.2 | 1.27 × 10¹² |
| Example 2 | | | | | | | |
| Comparative | — | — | Sulfuric acid | 0.049 | — | 2.0 | 9.51 × 10¹¹ |
| Example 3 | | | | | | | |
| Comparative | — | — | Sulfuric acid | 0.098 | — | 2.3 | 5.75 × 10¹¹ |
| Example 4 | | | | | | | |
| Comparative | Ascorbic acid | 0.1 | Sulfuric acid | 0.098 | 0.89 | 1.8 | 1.22 × 10¹² |
| Example 5 | | | | | | | |
| Comparative | Ascorbic acid | 0.26 | Sulfuric acid | 0.098 | 0.38 | 1.8 | 6.90 × 10¹¹ |
| Example 6 | | | | | | | |
| Comparative | Ascorbic acid | 0.44 | Sulfuric acid | 0.098 | 0.22 | 1.8 | 6.66 × 10¹¹ |
| Example 7 | | | | | | | |
| Comparative | Pyrogallol | 0.38 | Sulfuric acid | 0.005 | 0.01 | 3.1 | 1.18 × 10¹² |
| Example 8 | | | | | | | |
| Comparative | Pyrogallol | 0.38 | Sulfuric acid | 0.380 | 1.00 | 1.4 | 1.27 × 10¹² |
| Example 9 | | | | | | | |

As can be seen from Table 1, the cleaning liquids obtained in Examples 1 to 8 containing the component (A) and the component (B) simultaneously at a particular mass ratio (B)/(A) were excellent in the removability of cerium oxide.

On the other hand, the cleaning liquids obtained in Comparative Examples 1 to 9, in which either the component (A) or the component (B) was not contained or the component (A) and the component (B) were simultaneously contained but the mass ratio (B)/(A) was out of the predetermined range, were inferior in the removability of cerium oxide.

Although various embodiments have been described above, it goes without saying that the present invention is not limited to such examples. It is clear that those skilled in the art can come up with various changes or modifications within the scope of the claims, and it is understood that these also naturally fall within the technical scope of the present invention. In addition, each of the constituent elements in the above embodiments may be freely combined without departing from the spirit of the invention.

Note that the present application is based on Japanese patent application No. 2021-183700 filed on Nov. 10, 2021, the content of which is incorporated by reference into the present application.

### INDUSTRIAL APPLICABILITY

Because of excellent removability of the cerium compound on the silicon oxide film and/or the silicon nitride film, the cleaning liquid according to the present invention can be suitably used for the cleaning after the chemical mechanical polishing.

1. A cleaning liquid for removing a cerium compound, the cleaning liquid comprising the following component (A) and component (B), wherein a mass ratio of the component (B) to the component (A) is 0.05 to 0.6:
the component (A): a six-membered ring compound having two or more hydroxy groups; and
the component (B): an inorganic acid compound.

2. The cleaning liquid according to claim 1, wherein the component (A) contains at least one selected from the group consisting of catechol, resorcinol, hydroquinone, pyrogallol, and methylcatechol.

3. The cleaning liquid according to claim 1, wherein the component (A) contains pyrogallol.

4. The cleaning liquid according to claim 1, wherein the component (B) contains at least one selected from the group consisting of sulfuric acid, nitric acid, hydrochloric acid, phosphoric acid, and phosphorous acid.

5. The cleaning liquid according to claim 1, wherein the component (B) contains sulfuric acid.

6. The cleaning liquid according to claim 1, further comprising a component (C),
component (C): a water-soluble organic polymer.

7. The cleaning liquid according to claim 6, wherein the component (C) contains at least one selected from a polycarboxylic acid and a salt thereof.

8. The cleaning liquid according to claim 1, wherein the cleaning liquid has a pH of 1 to 4.

9. The cleaning liquid according to claim 1, which is used for cleaning after chemical mechanical polishing.

10. The cleaning liquid according to claim 1, which is used for removing the cerium compound on a silicon oxide film and/or a silicon nitride film.

11. A cleaning method comprising removing a cerium compound using the cleaning liquid according to claim 1.

12. A method for producing a semiconductor wafer, the method comprising: removing a cerium compound using the cleaning liquid according to claim 1.

13. The method for producing a semiconductor wafer according to claim 12, further comprising: performing chemical mechanical polishing using an abrasive containing a cerium compound.
